(19) United States
(12) Patent Application Publication
(10) Pub. No.: US 2024/0224725 A1
(43) Pub. Date: Jul. 4, 2024

(54) DISPLAY APPARATUS AND APPARATUS FOR MANUFACTURING DISPLAY APPARATUS

(71) Applicant: SAMSUNG DISPLAY CO., LTD., Yongin-Si (KR)

(72) Inventors: Daehyun Hwang, Yongin-Si (KR); Minhee Park, Yongin-Si (KR); Daewoo Lee, Yongin-Si (KR); Soyeon Joo, Yongin-Si (KR); Kyunghoon Chae, Yongin-Si (KR); Hyeondeuk Hwang, Yongin-Si (KR)

(21) Appl. No.: 18/395,908

(22) Filed: Dec. 26, 2023

(30) Foreign Application Priority Data
Dec. 30, 2022 (KR) 10-2022-0191046

(51) Int. Cl. H10K 59/80; H10K 71/00

(52) U.S. Cl. CPC H10K 59/873; H10K 71/00

(57) ABSTRACT

An apparatus for manufacturing the display apparatus includes a first mold that includes an open surface that accommodates a display module, a second mold that surrounds the first mold and accommodates the first mold, and a third mold coupled to the second mold to cover the accommodated display module, wherein a modulus of the first mold is lower than a modulus of the second mold.

### CROSS-REFERENCE TO RELATED APPLICATION

This application claims priority under 35 U.S.C. § 119 from Korean Patent Application No. 10-2022-0191046, filed on Dec. 30, 2022 in the Korean Intellectual Property Office, the contents of which are herein incorporated by reference in their entirety.

### TECHNICAL FIELD

One or more embodiments are directed to a display apparatus and an apparatus for manufacturing the display apparatus, and more particularly, to a display apparatus that increases a quality of a resin structure of a display apparatus and an apparatus for manufacturing a display apparatus.

### DISCUSSION OF THE RELATED ART

Recently, electronic devices have become widely used. A variety of electronic devices, such as mobile electronic devices and stationary electronic devices, are used, and such electronic devices include a display apparatus that can provide visual information, such as an image or video to support various functions, to a user.

Recently, as various components for driving a display apparatus have become miniaturized, the importance of the display apparatus for an electronic device has continually increased, and a structure to bend a flat display apparatus has been developed.

In addition, a display apparatus includes a resin structure connected to the electronic device.

### SUMMARY

One or more embodiments include a display apparatus that increases a quality of a resin structure of the display apparatus and an apparatus for manufacturing the display apparatus.

According to one or more embodiments, an apparatus for manufacturing a display apparatus includes a first mold that includes an open surface that accommodates a display module, a second mold that surrounds the first mold and accommodates the first mold, and a third mold coupled to the second mold so that the third mold covers the accommodated display module. A modulus of the first mold is lower than a modulus of the second mold.

The first mold may include silicon, and the second mold may include a metal.

The first mold may include a groove formed along a circumference of the accommodated display module. The groove is concave in a thickness direction of the first mold.

The groove may be defined by a vertical portion of the first mold that contacts the circumference of the display module and extends in a direction perpendicular to a display surface of the display module, a horizontal portion of the first mold that extends from the vertical portion toward a center of the first mold in a plan view, and a protrusion bump portion of the first mold that protrudes from the horizontal portion toward the display module.

In a plan view, a radius of an outer circumference of the groove may be less than a radius of an outer circumference of the display module.

The vertical portion may be chamfered at an entrance of the groove.

A portion at which the vertical portion and the horizontal portion are connected to each other may be chamfered.

The apparatus may further include an injecting portion through which resins are injected into an encapsulated space formed by the groove and the display module accommodated in the first mold and an ejecting portion through which the resins are ejected after the encapsulated space is completely filled with the resins, wherein, in a plan view, each of the injecting portion and the ejecting portion may be located inward from the groove in a radial direction in a plan view.

The injecting portion and the ejecting portion may be symmetrically arranged with respect to a center of the first mold, in a plan view.

Each of the injecting portion and the ejecting portion may be a through-hole that extends in a direction perpendicular to a display surface of the display module.

Inner surfaces of the injecting portion and the ejecting portion may include a same material as the first mold.

The first mold may further include an additional groove that is extends from the groove toward the center of the first mold in the plan view, and each of the injecting portion and the ejecting portion may be connected to the additional groove.

The additional groove may include a first additional groove connected to the injecting portion and a second additional groove connected to the ejecting portion, and the first additional groove and the second additional groove may be symmetrically arranged with respect to the center of the first mold in the plan view.

A depth of the additional groove may be less than a depth of the groove.

The apparatus may further include a coupling portion that couples the second mold with the third mold. The coupling portion may include a coupling hole that penetrates the second mold and the third mold and a fixing member inserted into the coupling hole.

According to one or more embodiments, a display apparatus includes a panel that includes a display panel and a support panel that supports the display panel, a cover window that covers the display panel at a side opposite to the support panel, and is larger than the display panel in a plan view, and a resin structure disposed along a circumference of the panel at a side opposite to the cover window with the panel between the resin structure and cover window. An outer circumferential surface of the resin structure includes a concave surface that is curved toward a center of the panel in the plan view.

The resin structure may include a circumferential member that forms a closed loop along the circumference of the panel and a circumferential protrusion portion that protrudes from the circumferential member toward the center of the panel in the plan view.

A thickness of the circumferential protrusion portion may be less than a thickness of the circumferential member.

The circumferential protrusion portion may include a first circumferential protrusion portion and a second circumferential protrusion portion. The first circumferential protrusion portion and the second circumferential protrusion portion may be symmetrically arranged with respect to the center of the panel in the plan view.

The resin structure may further include a cutting column that protrudes in a direction away from a surface of the panel, wherein the cutting column may be closer to the panel in a thickness direction than the circumferential member.

According to one or more embodiments, a method of manufacturing a display apparatus includes accommodating a first mold in a second mold, and accommodating a display module in the second mold, wherein the first mold includes a groove formed along a circumference of the display module, coupling a third mold to the second mold so that the third mold covers the display module, injecting resins through an injecting portion and into the groove, wherein the injecting portion penetrates the first and second molds, curing the resins by performing a thermosetting process so that a resin structure is formed along a circumference of the display module, wherein a circumferential protrusion portion of the resin structure is formed at a position that corresponds to the injecting portion and the ejecting portion; and removing the first, second and third molds from the display module, and cutting residues of the resins so that a cutting column that protrudes from the circumferential protrusion portion of the resin structure is formed.

The display module may include a cover window, a vertical portion of the first mold may surround an outer circumference of the cover window of the display module, a horizontal portion may extend from the vertical portion in an inwardly radial direction, and a protrusion bump portion may protrude from the horizontal portion toward the panel.

The second mold and the third mold may be coupled to each other through a coupling hole and a fixing member that includes a thread.

The resins may be injected into a first additional groove connected to the groove. The injected resins may completely fill an encapsulated space between the groove and the display module, and overflowing resins may be ejected through an ejecting portion that penetrates the first and second molds.

### BRIEF DESCRIPTION OF THE DRAWINGS

FIG. 1 is a perspective view of a display apparatus according to an embodiment.

FIG. 2 is a cross-sectional view of a display panel taken along line II-II′ of FIG. 1, according to an embodiment.

FIG. 3 is a bottom view of a display apparatus according to an embodiment.

FIG. 4 is a cross-sectional view of a display apparatus taken along line IV-IV′ of FIG. 3, according to an embodiment.

FIG. 5 is a cross-sectional view of a display apparatus taken along line V-V′ of FIG. 3, according to an embodiment.

FIGS. 6A and 6B are perspective views of an apparatus for manufacturing a display apparatus, according to an embodiment.

FIG. 7 is a cross-sectional view of an apparatus for manufacturing a display apparatus taken along line VII-VII′ of FIG. 6B, according to an embodiment.

FIG. 8 is a cross-sectional view of an apparatus for manufacturing a display apparatus taken along line VIII-VIII′ of FIG. 6B, according to an embodiment.

FIG. 9 is a cross-sectional view of an apparatus for manufacturing a display apparatus, according to another embodiment.

FIGS. 10 to 14 illustrate a method of manufacturing a display apparatus according to an embodiment.

### DETAILED DESCRIPTION

Reference will now be made in detail to embodiments, examples of which are illustrated in the accompanying drawings, wherein like reference numerals may refer to like elements throughout. In this regard, embodiments may have different forms and should not be construed as being limited to the descriptions set forth herein.

Hereinafter, embodiments of the disclosure will be described in detail by referring to the accompanying drawings. In descriptions with reference to the drawings, the same reference numerals may be given to elements that are the same or substantially the same and descriptions will not be repeated.

It will be understood that when a layer, region, or element is referred to as being formed “on” another layer, area, or element, it can be directly or indirectly formed on the other layer, region, or element.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

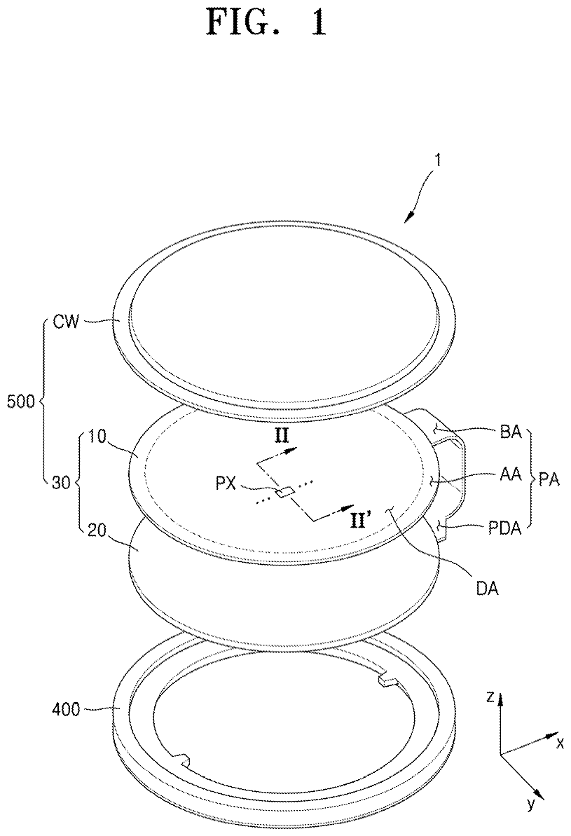

FIG. 1 is a perspective view of a display apparatus 1 according to an embodiment.

Referring to FIG. 1, in an embodiment, the display apparatus 1 can display a video image or a still image and provides a screen for inputting or outputting data to or from an electronic device. FIG. 1 illustrates an embodiment of the display apparatus 1 that can be used in a smart watch. However, the display apparatus 1 is not necessarily limited thereto, and the display apparatus 1 can be used as a display screen not only for a portable electronic device, such as a mobile phone, a smart phone, a tablet personal computer (PC), a mobile communication terminal, an electronic notebook, an electronic book, a portable multimedia player (PMP), a navigation device, or an ultra-mobile PC (UMPC), but also for various other products, such as a television, a notebook computer, a monitor, a broadcasting panel, or an Internet of things (IOT) device. In addition, the display apparatus 1 according to an embodiment can be used in an electronic device, such as a wearable device that includes a smart watch, a watch phone, a glasses-type display, or a head-mounted display (HMD). In addition, the display apparatus 1 according to an embodiment can be used as a display screen of various other electronic devices, such as: a center information display (CID) on a gauge of a vehicle or a center fascia or a dashboard of the vehicle; a room mirror display that substitutes for a side-view mirror of a vehicle; or a display disposed on a rear surface of a front seat, as an entertainment device for a passenger in the backseat of a vehicle.

As illustrated in FIG. 1, the display apparatus 1 may have an approximately circular shape. However, embodiments of the disclosure are not necessarily limited thereto. For example, in other embodiments, the display apparatus 1 has a polygonal shape, such as an approximately rectangular shape, or an oval shape. For example, in an embodiment, the display apparatus 1 generally has a rectangular planar shape having a short side that extends in a first direction, such as an x direction, and a long side that extends in a second direction, such as a y direction. Alternatively, in an embodiment, the display apparatus 1 has a rectangular planar shape that has a long side that extends in the first direction and a short side that extends in the second direction, or may have a square shape having sides of equal length that extend in the first direction and the second direction. Hereinafter, for convenience of description, a case where the display apparatus 1 has an approximately circular shape, as illustrated in FIG. 1, will be mainly described.

The display apparatus 1 includes a display module 500 and a resin structure 400. The display module 500 includes a panel 30 and a cover window CW, and the panel 30 includes a display panel 10 and a support panel 20.

The display panel 10 displays information processed by the display apparatus 1. For example, the display panel 10 displays execution information of an application being executed by the display apparatus 1 or displays user interface (UI) or graphics user interface (GUI) information based on the execution information.

The display panel 10 includes a display element. For example, the display panel 10 is one of an organic light-emitting display panel that uses an organic light-emitting diode, a micro light-emitting diode display panel that uses a micro light-emitting diode, a quantum-dot light-emitting display panel that uses a quantum-dot light-emitting diode that includes a quantum-dot emission layer, or an inorganic light-emitting display panel that uses an inorganic light-emitting diode that includes an inorganic semiconductor. Hereinafter, a case where the display panel 10 includes an organic light-emitting display panel that uses an organic light-emitting diode as a display element will be mainly described in detail.

In addition, the display panel 10 includes a display area DA and a peripheral area PA. The display area DA is for displaying an image, and has a circular shape, according to an embodiment. However, the display area DA is not necessarily limited thereto, and the display area DA may have a polygonal shape such as a rectangular shape, or an oval shape.

Pixels PX are disposed in the display area DA. The display panel 10 provides an image by using light emitted from the pixels PX. Each pixel PX emits light by using a display element. According to an embodiment, each pixel PX emits one of red, green, or blue light. According to an embodiment, each pixel PX emits one of red, green, blue, or white light.

The peripheral area PA corresponds to a non-display area that does not provide an image. The peripheral area PA at least partially surrounds the display area DA. For example, in an embodiment, the peripheral area PA entirely surrounds the display area DA. A driver that provides an electrical signal to the pixels PX, power lines that transmit power to the pixels PX, etc., are arranged in the peripheral area PA.

According to an embodiment, the peripheral area PA includes an adjacent area AA, a bendable area BA, and a pad area PDA. The adjacent area AA is adjacent to the display area DA and surrounds the display area DA.

The pad area PDA spaced apart from the adjacent area AA. Drivers that supply a signal or a voltage to the pixels PX are disposed in the pad area PDA. According to an embodiment, a display circuit board is connected to the pad area PDA. The display circuit board may include a flexible printed circuit board (FPCB) that is bendable, or a rigid printed circuit board (RPCB) that is substantially rigid. Alternatively, in an embodiment, the display circuit board includes a complex printed circuit board that includes both an RPCB and an FPCB.

A driver that provides an electrical signal or supplies power to the pixels PX is disposed on the display circuit board.

The bendable area BA is disposed between the adjacent area AA and the pad area PDA. The display panel 10 is bent in the bendable area BA. For example, the display panel 10 can be bent in the bendable area BA to be curved toward a thickness direction that is perpendicular to a display surface. Thus, at least portions of a lower surface of the display panel 10 face each other, and the pad area PDA of the display panel 10 is arranged below the display area DA. Thus, an area of the peripheral area PA that is seen by a user can be reduced.

The support panel 20 is disposed below the display panel 10, on a surface that is opposite to the display surface of the display panel 10. The support panel 20 supports the display panel 10 and protects the display panel 10 from external shocks. According to an embodiment, the support panel 20 is disposed on the opposite surface of the display panel 10, and then the display panel 10 is bent in the bendable area BA. Thus, the support panel 20 is arranged between the display arca DA and the pad area PDA of the display panel 10.

The cover window CW is disposed on and covers the display surface of the display panel 10. The cover window CW protects the display panel 10. The cover window CW includes a transmissive material, and the cover window CW includes glass or polymer resins. The cover window CW includes, for example, a polymer resin, such as at least one of polyethersulphone, polyacrylate, polyetherimide, polyethylene naphthalate, polyethylene terephthalate, polyphenylene sulfide, polyarylate, polyimide, polycarbonate, or cellulose acetate propionate.

The resin structure 400 is arranged below the display module 500, on the opposite surface of the display module 500. For example, the resin structure 400 is disposed on a side opposite to the cover window CW with the display panel 10 and the support panel 20 interposed between the resin structure 400 and the cover window CW. According to an embodiment, the resin structure 400 has a closed loop along a circumference of the display module 500. However, according to an embodiment, the resin structure 400 is disposed only at a portion of the circumference of the display module 500 and is spaced apart from the display module 500. For example, when the display module 500 has a rectangular shape, the resin structure 400 is disposed on one of the four sides that form the circumference of the display module 500. Hereinafter, for convenience of description, a case where the resin structure 400 is a closed loop along the circumference of the display module 500 will be mainly described.

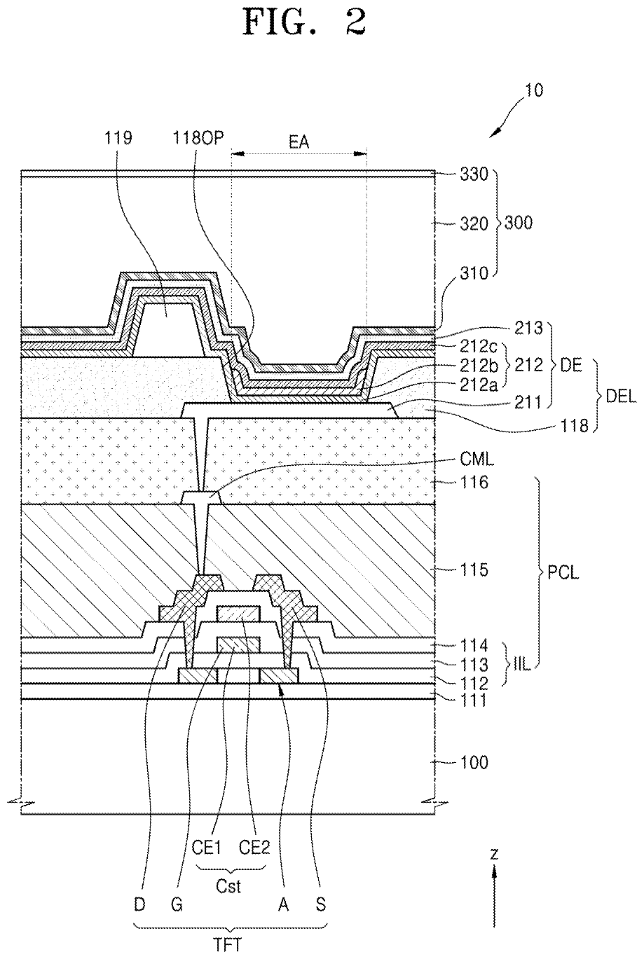

FIG. 2 is a cross-sectional view of the display panel 10 taken along line II-II′ of FIG. 1, according to an embodiment.

Referring to FIG. 2, in an embodiment, the display panel 10 includes a substrate 100, a buffer layer 111, a pixel circuit layer PCL, a display element layer DEL, and an encapsulation layer 300.

The substrate 100 may include glass, or polymer resins, such as at least one of polyethersulfone, polyarylate, polyetherimide, polyethylene naphthalate, polyethylene terephthalate, polyphenylene sulfide, polyimide, polycarbonate, cellulose tri acetate, or cellulose acetate propionate. According to an embodiment, the substrate 100 has a multi-layered structure that includes a base layer that includes the above described polymer resins and a barrier layer. The substrate 100 that includes the polymer resins is flexible, rollable, or bendable.

The buffer layer 111 is disposed on the substrate 100. The buffer layer 111 includes an inorganic insulating material, such as SiNₓ, SiON, and SiO₂, and may include a single layer or multiple layers that include the above described inorganic insulating material.

The pixel circuit layer PCL is disposed on the buffer layer 111. The pixel circuit layer PCL includes a thin-film transistor TFT in a pixel circuit, an inorganic insulating layer IIL, a first planarization layer 115, and a second planarization layer 116 disposed below or/and above the components of the thin-film transistor TFT. The inorganic insulating layer IIL includes a first gate insulating layer 112, a second gate insulating layer 113, and an interlayer insulating layer 114.

The thin film transistor TFT includes a semiconductor layer A, and the semiconductor layer A may include polysilicon. Alternatively, the semiconductor layer A may include at least one of amorphous silicon, an oxide semiconductor, or an organic semiconductor. The semiconductor layer A includes a channel area, a drain area and a source area arranged at both sides of the channel area, respectively. A gate electrode G overlaps the channel area.

The gate electrode G includes a low-resistance metal. The gate electrode G includes a conductive material that includes at least one of Mo, Al, Cu, Ti, etc., and may include multiple layers or a single layer that include the above described conductive materials.

The first gate insulating layer 112 is interposed between the semiconductor layer A and the gate electrode G and includes an inorganic insulating material, such as at least one of SiO₂, SiNₓ, SiON, Al₂O₃, TiO₂, Ta₂O₅, HfO₂, or ZnOₓ, etc. ZnOₓ includes ZnO and/or ZnO₂.

The second gate insulating layer 113 is disposed on to the first gate insulating layer 112 and covers the gate electrode G. Similar to the first gate insulating layer 112, the second gate insulating layer 113 includes an inorganic insulating material, such as at least one of SiO₂, SiNₓ, SiON, Al₂O₃, TiO₂, Ta₂O₅, HfO₂, or ZnOₓ, etc. ZnOₓ includes ZnO and/or ZnO₂.

An upper electrode CE2 of a storage capacitor Cst is is disposed above the second gate insulating layer 113. The upper electrode CE2 overlaps the gate electrode G therebelow. The gate electrode G and the upper electrode CE2 that overlap each other with the second gate insulating layer 113 therebetween form a storage capacitor Cst of the pixel circuit. For example, the gate electrode G functions as a lower electrode CE1 of the storage capacitor Cst. As described above, the storage capacitor Cst and the thin-film transistor TFT overlap each other. According to some embodiments, the storage capacitor Cst does not overlap the thin-film transistor TFT.

The upper electrode CE2 includes at least one of Al, Pt, Pd, Ag, Mg, Au, Ni, Nd, Ir, Cr, Ca, Mo, Ti, W, and/or Cu, and may include a single layer or multiple layers that include the above-described materials.

The interlayer insulating layer 114 is disposed on the second gate insulating layer 113 and covers the upper electrode CE2. The interlayer insulating layer 114 include at least one of SiO₂, SiNₓ, SION, Al₂O₃, TiO₂, Ta₂O₅, HfO₂, or ZnOₓ, etc. ZnOₓ includes ZnO and/or ZnO₂. The interlayer insulating layer 114 may include a single layer or multiple layers that include the above described inorganic insulating materials.

Each of a drain electrode D and a source electrode S is disposed on the interlayer insulating layer 114. The drain electrode D and the source electrode S each include a highly conductive material. For example, the highly conductive material includes at least one of Mo, Al, Cu, or Ti, etc., and may include multiple layers or a single layer that includes the above described materials. According to an embodiment, the drain electrode D and the source electrode S each have a multi-layered structure of Ti/Al/Ti.

The first planarization layer 115 is disposed on the interlayer insulating layer 114 and covers the drain electrode D and the source electrode S. The first planarization layer 115 includes an organic insulating layer. The first planarization layer 115 includes an organic insulating material, such as at least one of a general-purpose polymer such as polymethylmethacrylate (PMMA) or polystyrene (PS), a polymer derivative that includes a phenol-based group, an acryl-based polymer, an imide-based polymer, an aryl ether-based polymer, an amide-based polymer, a fluorine-based polymer, a p-xylene-based polymer, or a vinyl alcohol-based polymer, or a blend thereof.

A connection electrode CML is disposed on the first planarization layer 115. The connection electrode CML is connected to one of the drain electrode D or the source electrode S through a contact hole in the first planarization layer 115. The connection electrode CML includes a highly conductive material. The highly conductive material includes at least one of Mo, Al, Cu, or Ti, etc., and may include multiple layers or a single layer that includes the above described conductive materials. According to an embodiment, the connection electrode CML has a multi-layered structure of Ti/Al/Ti.

The second planarization layer 116 is disposed on the first planarization layer 115 and covers the connection electrode CM. The second planarization layer 116 includes an organic insulating layer. The organic insulating layer includes an organic insulating material, such as a at least one of a general-purpose polymer such as PMMA or PS, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, or a blend thereof.

The display element layer DEL is disposed on the pixel circuit layer PCL. The display element layer DEL is disposed on the second planarization layer 116 of the pixel circuit layer PCL. The display element layer DEL includes a display element DE. The display element DE includes an organic light-emitting diode OLED. A pixel electrode 211 of the display element DE is electrically connected to the connection electrode CML through a contact hole in the second planarization layer 116.

The pixel electrode 211 includes a conductive oxide, such as at least one of indium tin oxide (ITO), indium zinc oxide (IZO), zinc oxide (ZnO), indium oxide (In₂O₃), indium gallium oxide (IGO), or aluminum zinc oxide (AZO). According to an embodiment, the pixel electrode 211 includes a reflective layer that includes at least one of Ag, Mg, Al, Pt, Pd, Au, Ni, Nd, Ir, or Cr, or a compound thereof. According to an embodiment, the pixel electrode 211 further includes a layer that includes at least one of ITO, IZO, ZnO, or In₂O₃ above/below the above described reflective layer.

A pixel-defining layer 118 that includes an opening 118OP that exposes a central portion of the pixel electrode 211 is disposed on the pixel electrode 211 and the second planarization layer 116. The pixel-defining layer 118 may include an organic insulating material and/or an inorganic insulating material. The opening 118OP defines an emission area EA of light emitted from the display element DE. For example, a width of the opening 118OP corresponds to a width of the emission area EA of the display element DE.

According to an embodiment, the pixel-defining layer 118 includes a light-shielding material and is black. The light-shielding material includes at least one of a resin or paste that includes carbon black, a carbon nano-tube, a black dye, a metal particle, such as one of Ni, Al, or Mo, or an alloy thereof, a metal oxide particle, such as chromium oxide, a metal nitride particle, such as chromium nitride, etc. When the pixel-defining layer 118 includes a light-shielding material, reflection of external light due to metal structures below the pixel-defining layer 118 can be reduced.

A spacer 119 is disposed on the pixel-defining layer 118. The spacer 119 prevents fracturing of the substrate 100 when a display apparatus is manufactured. In a manufacturing process of the display panel, a mask sheet is used. The spacer 119 prevents damage or fractures that can occur to a portion of the substrate 100 due to the mask sheet when the mask sheet is inserted into the opening 118OP of the pixel-defining layer 118 or is adhered to the pixel-defining layer 118, to deposit a deposition material on the substrate 100.

In an embodiment, the spacer 119 includes an organic insulating material, such as polyimide. In some embodiments, the spacer 119 includes an inorganic insulating material, such as SiNₓ or SiO₂, or includes an organic insulating material and an inorganic insulating material.

According to an embodiment, the spacer 119 includes a different material from the pixel-defining layer 118. Alternatively, according to an embodiment, the spacer 119 includes the same material as the pixel-defining layer 118, and the pixel-defining layer 118 and the spacer 119 are formed together by a mask process that uses a halftone mask, etc.

An intermediate layer 212 of the OLED is arranged on the pixel-defining layer 118 and the pixel electrode 211. The intermediate layer 212 includes an emission layer 212b disposed on the pixel electrode 211 in the opening 118OP of the pixel-defining layer 118. The emission layer 212b includes a high molecular-weight or low molecular-weight organic material that emits a predetermined color of light.

A first functional layer 212a and a second functional layer 212c are disposed above and below the emission layer 212b, respectively. The first functional layer 212a is disposed below the emission layer 212b and includes, for example, a hole transport layer (HTL), or an HTL and a hole injection layer (HIL). The second functional layer 212c is disposed above the emission layer 212b and may be optionally arranged. The second functional layer 212c includes an electron transport layer (ETL) and/or an electron injection layer (EIL). The first functional layer 212a and/or the second functional layer 212c form a common layer that entirely covers the substrate 100, such as an opposite electrode 213 to be described below.

An opposite electrode 213 of the OLED is disposed on the intermediate layer 212 and includes a conductive material that has a low work function. For example, the opposite electrode 213 includes a (semi-) transparent layer that includes at least one of Ag, Mg, Al, Pt, Pd, Au, Ni, Nd, Ir, Cr, Li, or Ca, or an alloy thereof. Alternatively, in an embodiment, the opposite electrode 213 further includes a layer that includes at least one of ITO, IZO, or ZnO, or In₂O₃ on the (semi-) transparent layer.

According to some embodiments, a capping layer is further disposed on the opposite electrode 213. The capping layer may include LiF, an inorganic material, or/and an organic material.

The encapsulation layer 300 is disposed on the opposite electrode 213. According to an embodiment, the encapsulation layer 300 includes at least one inorganic encapsulation layer and at least one organic encapsulation layer. FIG. 2 shows that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 include at least one inorganic material selected from aluminum oxide, titanium oxide, tantalum oxide, hafnium oxide, ZnO, SiOₓ, SiNₓ, or SiON. The organic encapsulation layer 320 includes a polymer-based material. The polymer-based material includes at least one of an acryl-based resin, an epoxy-based resin, polyimide, or polyethylene, etc. According to an embodiment, the organic encapsulation layer 320 includes acrylate.

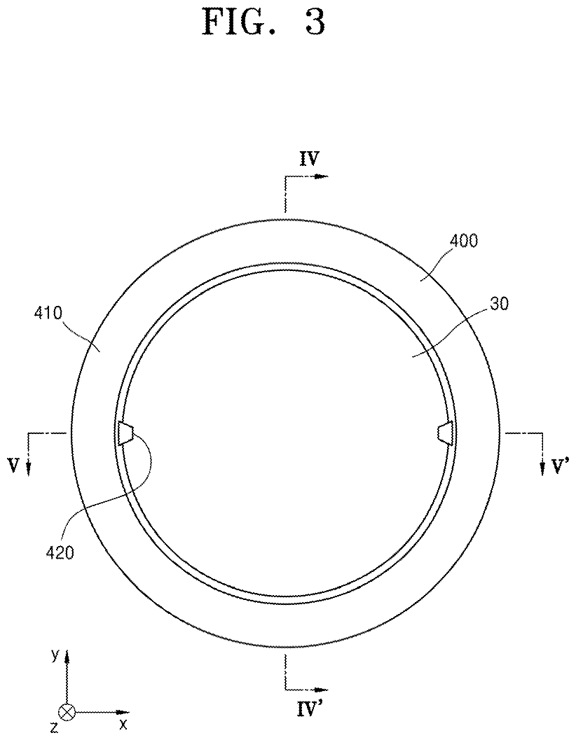

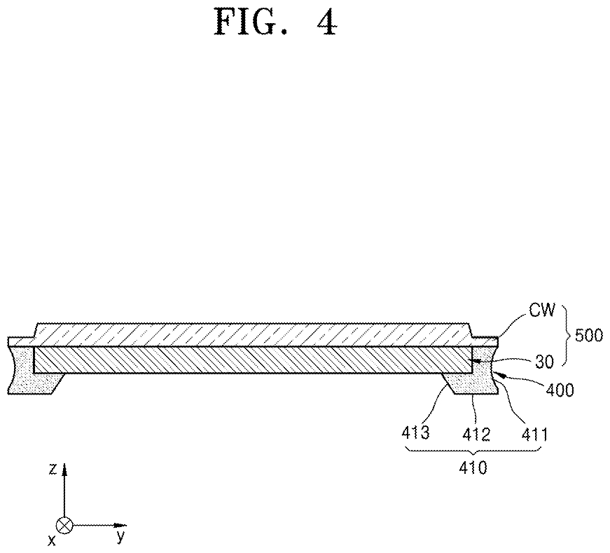

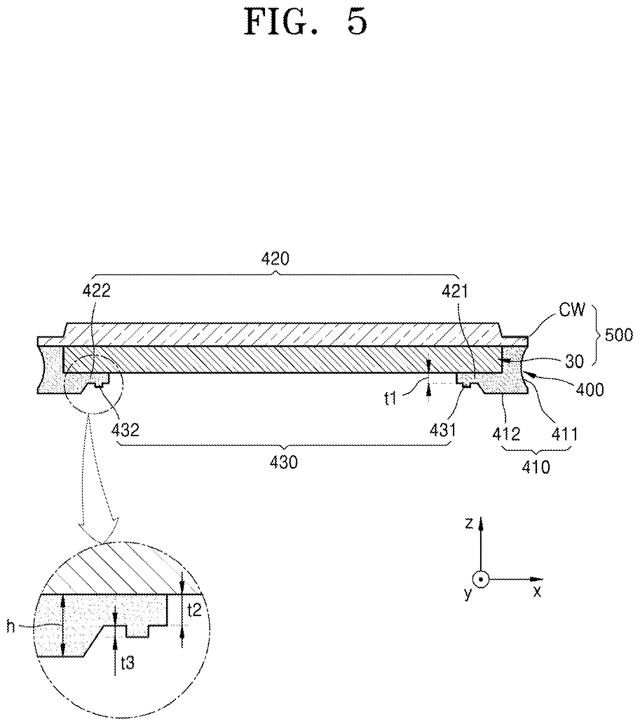

FIG. 3 is a bottom view of the display apparatus 1 according to an embodiment. FIG. 4 is a cross-sectional view of the display apparatus 1 taken along line IV-IV′ of FIG. 3, according to an embodiment. FIG. 5 is a cross-sectional view of the display apparatus 1 taken along line IV-IV′ of FIG. 3, according to an embodiment.

Referring to FIGS. 3 and 4, in an embodiment, the cover window CW is disposed on a display surface of the panel 30. In a plan view, the cover window CW is larger than the panel 30 so as to cover the panel 30.

The resin structure 400 is disposed on an opposite side of the display surface of the panel 30. When the display apparatus 1 is used in an electronic device, the resin structure 400 provides a connection point through which the display apparatus 1 is coupled to the electronic device.

According to an embodiment, the resin structure 400 includes resins. As described below, the resin structure 400 is formed by injecting resins into a mold in which the display module 500 is accommodated and curing the resins.

The resin structure 400 includes a circumferential member 410. The circumferential member 410 is a closed loop formed along a circumference of the display module 500. The circumferential member 410 covers a lower surface, such as a surface in a −z direction of FIG. 4, of a circumference of the cover window CW and covers a lower surface, such as a surface in the −z direction of FIG. 4, of a circumference of the panel 30.

According to an embodiment, the circumferential member 410 includes a first surface 411, a second surface 412, and a third surface 413. The first surface 411 extends from the cover window CW in a thickness direction, such as a z direction of FIG. 4. The first surface 411 forms an outer circumference of the circumferential member 410. According to an embodiment, the first surface 411 is an inwardly curved concave surface. For example, the first surface 411 is a curved surface that is concave in a direction from a circumference of the display module 500 toward a center of the display module 500. This may be due to a manufacturing process of the resin structure 400, as described below. The resin structure 400 is manufactured by using a mold having a low modulus, such as silicon, and the mold is pressured to be inwardly concave, and thus, the circumferential member 410 is provided with a curved concave surface.

The second surface 412 extends direction from the first surface 411 in a direction perpendicular to a thickness, that is, a direction. such as a y or −y direction of FIG. 4, toward the center of the display module 500 in a plan view. The second surface 412 forms a lower boundary of the circumferential member 410.

The third surface 413 extends from the second surface 412 in an approximately thickness direction and connects to the panel 30. According to an embodiment, the third surface 413 is obliquely connected to the panel 30, but is not necessarily limited thereto.

Referring to FIGS. 3 and 5, according to an embodiment, the resin structure 400 further includes a circumferential protrusion portion 420. The circumferential protrusion portion 420 protrudes from the circumferential member 410 in an inwardly radial direction, that is, a direction, such as an x or −x direction of FIG. 5, toward the center of the display module 500. The circumferential protrusion portion 420 protrudes from the third surface 413 in the inwardly radial direction, such as a direction toward the center of the display module 500.

According to an embodiment, the circumferential protrusion portion 420 includes a first circumferential protrusion portion 421 and a second circumferential protrusion portion 422. In a plan view, the first circumferential protrusion portion 421 and the second circumferential protrusion portion 422 are spaced apart from each other along the circumference of the circumferential member 410. In other words, an angle between the first circumferential protrusion portion 421 and the second circumferential protrusion portion 422 may be greater than 0 degrees and less than or equal to 180 degrees.

In an embodiment, the first circumferential protrusion portion 421 and the second circumferential protrusion portion 422 are symmetrically arranged with respect to the center of the display module 500 in the plan view. For example, the angle between the first circumferential protrusion portion 421 and the second circumferential protrusion portion 422 is 180 degrees. As described below, this is because a portion into which resins are injected and a portion from which the resins are ejected to manufacture the resin structure 400 are arranged opposite to each other.

In addition, a thickness t1 of the first circumferential protrusion portion 421 is less than a thickness of the circumferential member 410, that is, a distance h from a surface of the panel 30 to the second surface 412 of the circumferential member 410. In addition, a thickness t2 of the second circumferential protrusion portion 422 is less than the thickness of the circumferential member 410, that is, the distance h from a surface of the panel 30 to the second surface 412 of the circumferential member 410. As described below, this is because the portion into which resins are injected and the portion from which the resins are ejected to manufacture the resin structure 400 are arranged closer to the panel 30 than the second surface 412.

According to an embodiment, the resin structure 400 further includes a cutting column 430. The cutting column 430 protrudes from the circumferential protrusion portion 420 in direction, such as a −z direction of FIG. 5, away from a surface of the panel 30. The cutting column 430 includes a first cutting column 431 that protrudes from the first circumferential protrusion portion 421 and a second cutting column 432 that protrudes from the second circumferential protrusion portion. A sum of the thickness t1 of the first circumferential protrusion portion 421 and a thickness t3 of the first cutting column 431 from a surface of the panel 30 is less than the distance h from a surface of the panel 30 to the second surface 412 of the circumferential member 410. For example, a distance from a surface of the panel 30 to a lower surface of the first cutting column 431 is less than the distance h from a surface of the panel 30 to the second surface 412 of the circumferential member 410. For example, the first cutting column 431 is closer to the panel 30 in a thickness direction than the second surface 412 of the circumferential member 410. The first cutting column 431 is formed by injecting resins and cutting the cured resins, in a manufacturing process of the resin structure 400. The second cutting column 432 is the same or substantially the same as the first cutting column 431, and thus, its detailed description is omitted hereinafter.

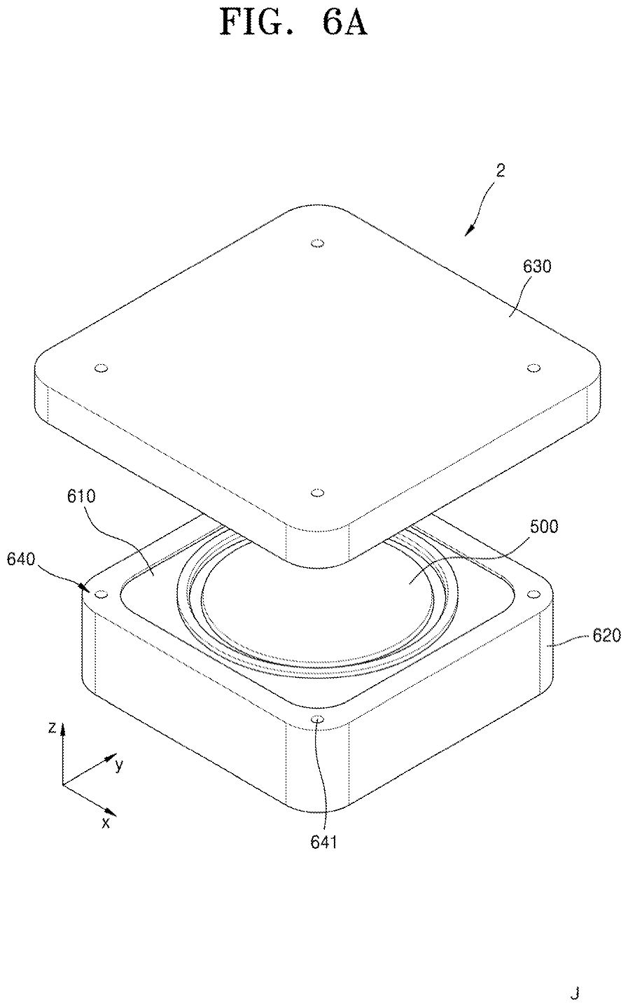

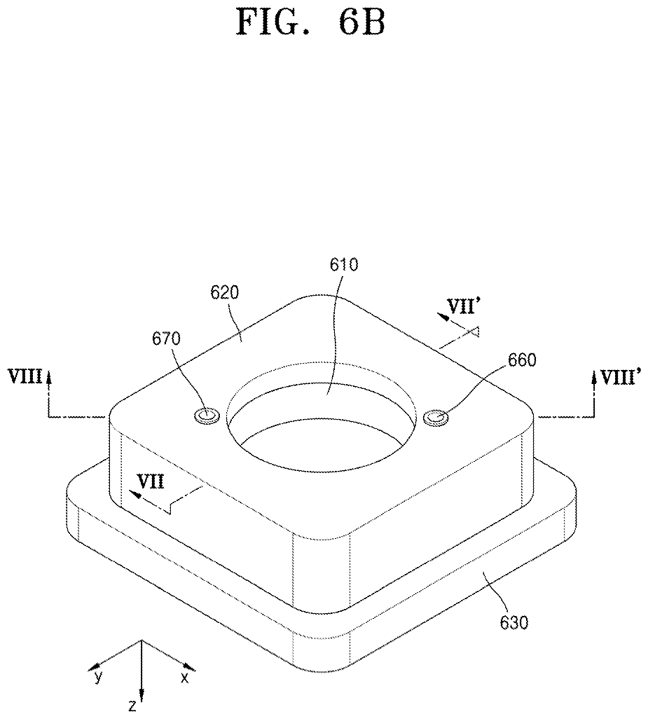

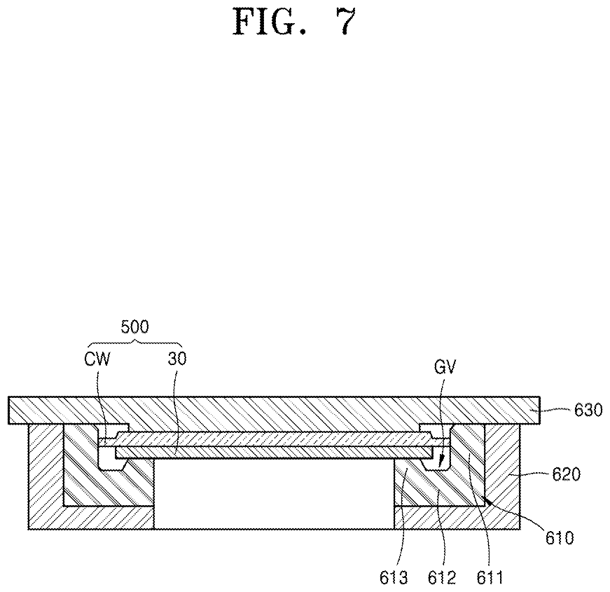

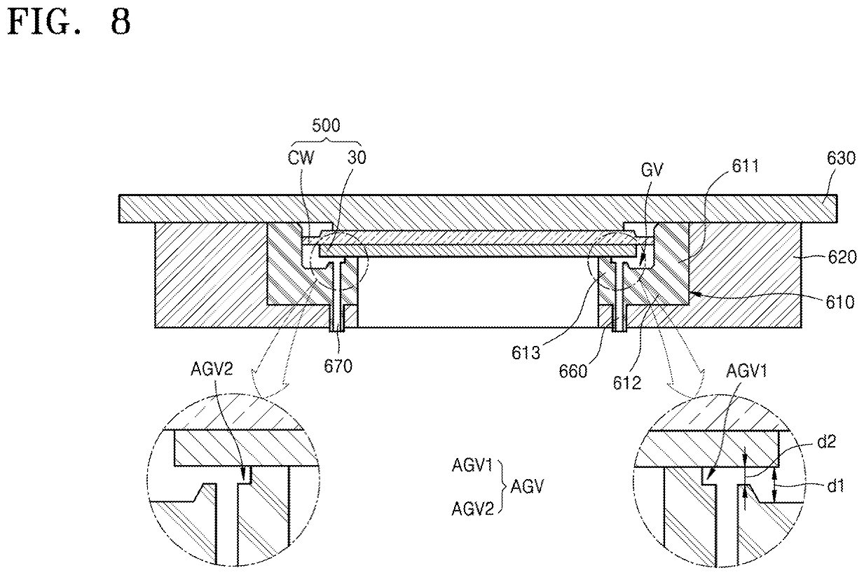

FIGS. 6A and 6B are perspective views of an apparatus 2 for manufacturing a display apparatus, according to an embodiment. FIG. 7 is a cross-sectional view of the apparatus 2 for manufacturing a display apparatus taken along line VII-VII′ of FIG. 6B, according to an embodiment. FIG. 8 is a cross-sectional view of the apparatus 2 for manufacturing a display apparatus taken along line VIII-VIII′ of FIG. 6B, according to an embodiment.

Referring to FIGS. 6A, 6B, and 7, in an embodiment, the apparatus 2 for manufacturing a display apparatus may be an apparatus for manufacturing the resin structure 400 (see FIG. 1) of the display apparatus 1 (see FIG. 1). The apparatus 2 may be used to manufacture the display apparatus 1, but is not necessarily limited thereto. Hereinafter, for convenience of description, a state in which the display module 500 is accommodated and mounted in the apparatus 2 for manufacturing a display apparatus will be mainly described.

The apparatus 2 for manufacturing a display apparatus according to an embodiment includes a first mold 610, a second mold 620, and a third mold 630.

The first mold 610 accommodates the display module 500. For example, the first mold 610 has an inner space and accommodates the display module 500 while facing the panel 30 of the display module 500. Accordingly, the panel 30 of the display module 500 contacts the first mold 610, and the cover window CW of the display module 500 faces outward toward an opening.

The second mold 620 accommodates the first mold 610 by surrounding the first mold 610. The second mold 620 is arranged at an outer body of the first mold 610 and is coupled to the third mold 630. A modulus of the first mold 610 is lower than a modulus of the second mold 620, according to an embodiment. For example, the first mold 610 includes silicon, and the second mold 620 include a metal.

The third mold 630 covers the display module 500 accommodated in the first mold 610 and encapsulates the first mold 610. The third mold 630 covers the display module 500 and contacts the cover window CW of the display module 500. In addition, the third mold 630 is bound and fixed with the second mold 620. According to an embodiment, a modulus of the third mold 630 is equal to the modulus of the second mold 620. For example, the third mold 630 includes the same material as the second mold 620, such as a metal.

Hereinafter, the shapes of the first to third molds 610 to 630 will be described in more detail. According to an embodiment, the first mold 610 includes a groove GV formed along an outer circumference of the display module 500 accommodated in the first mold 610. The groove GV forms a space that is concave in a thickness direction of the first mold 610, along the circumference of the display module 500. According to an embodiment, the groove GV has a closed-loop shape such as a ring, and this shape corresponds to a shape of the circumferential member 410 (see FIG. 4) of the display module 500 described above.

The groove GV is defined by a vertical portion 611, a horizontal portion 612, and a protrusion bump portion 613 of the first mold 610. For example, the vertical portion 611 forms an outer circumference of the groove GV and extends in a vertical direction, that is, a direction perpendicular to a display surface of the display module 500. The horizontal portion 612 forms a lower surface of the groove GV and extends from the vertical portion 611 in a horizontal direction, for example, toward a center of the first mold 610 in a plan view. The protrusion bump portion 613 forms an inner circumference of the groove GV, is connected to the horizontal portion 612 and protrudes in the vertical direction.

The cover window CW of the display module 500 is inserted into the outer circumference of the groove GV, that is, the vertical portion 611. An encapsulation is formed between the vertical portion 611 and an outer circumference of the cover window CW. For example, the first mold 610 includes the low modulus material, such as silicon, and thus, the cover window CW can be tightly inserted into the vertical portion 611 of the first mold 610. For example, according to an embodiment, a radius of the outer circumference of the groove GV is less than a radius of the outer circumference of the cover window CW. This allows a relatively tight encapsulation between the cover window CW and the first mold 610. In addition, the protrusion bump portion 613 protrudes toward the display module 500 and encapsulates the display module 500.

Therefore, the vertical portion 611, the horizontal portion 612, the protrusion bump portion 613, and the display module 500 form an encapsulated space. Resins are injected into this space, and thus, the circumferential member 410 described above is formed.

In an embodiment, a connection portion of the vertical portion 611 and the horizontal portion 612 is chamfered. This prevents an incomplete filling of resins due to formation of a bubble trap at an edge between the vertical portion 611 and the horizontal portion 612, when the resins are injected into the groove GV.

In addition, according to an embodiment, the vertical portion 611 is chamfered at an entrance of the groove GV. For example, the groove GV has an increased outer circumference at the entrance and has a gradually decreased outer circumference in the downward extension direction of the vertical portion 611. The chamfered slope allows easier accommodation of the display module 500 in the first mold 610.

The second mold 620 accommodates the first mold 610 by surrounding the first mold 610. The second mold 620 includes a more rigid material than the first mold 610.

The third mold 630 covers the display module 500 accommodated in the first mold 610. A rigidity of a material of the third mold 630 is the same as a rigidity of a material of the second mold 620. In addition, the third mold 630 is coupled and fixed to the second mold 620 that surrounds the first mold 610, and covers the display module 500.

According to an embodiment, the apparatus 2 for manufacturing a display apparatus further includes a coupling portion 640. The coupling portion 640 solidly couple and fix the second mold 620 to the third mold 630. According to an embodiment, the coupling portion 640 includes a coupling hole 641 and a fixing member. In an embodiment, the coupling hole 641 penetrates the third mold 630 and a portion of the second mold 620. In an embodiment, the coupling hole 641 penetrates the second mold 620 and a portion of the third mold 630. A thread is formed in the coupling hole 641. The fixing member, such as a bolt that has a thread, is inserted into the bonding hole 641. Accordingly, a coupling is formed between the second mold 620 and the third mold 630. According to an embodiment, a plurality of coupling holes 641 are formed along a circumference of the second mold 620 in a plan view. For example, four coupling holes 641 are formed as illustrated in FIG. 6A. In addition, a plurality of coupling holes 641 are formed along a circumference of the third mold 630 in a plan view. For example, four coupling holes 641 are formed as illustrated in FIG. 6A.

As described above, according to the apparatus 2 for manufacturing a display apparatus according to an embodiment, the mold portion into which resins are to be injected to form the resin structure 400 includes a low modulus material to secure a relatively solid encapsulation with the display module 500. In addition, the second mold 620 and the third mold 630 include a high modulus material, such as a highly rigid material, to be relatively more solidly coupled to each other.

Referring to FIGS. 6A, 6B, and 8, in an embodiment, the apparatus 2 for manufacturing a display apparatus further includes an injecting portion 660 and an ejecting portion 670. The injecting portion 660 provides a path for injecting the resins into the encapsulated space formed by the first mold 610 and the display module 500. The ejecting portion 670 provides a path by which the resins, which were injected through the injecting portion 660, are ejected, after completely filling the groove GV. Each of the injecting portion 660 and the ejecting portion 670 is formed as through-holes that penetrate the first mold 610 and the second mold 620. In addition, inner surfaces of the injecting portion 660 and the ejecting portion 670 include the same material as the first mold 610.

According to an embodiment, the injecting portion 660 and the ejecting portion 670 are located inward from the groove GV in a radial direction. For example, the injecting portion 660 and the ejecting portion 670 are closer to the center of the first mold 610 than the groove GV in a plan view. The injecting portion 660 and the ejecting portion 670 are through-holes that extend in the vertical direction, such as a direction perpendicular to the display surface of the display module 500. For example, the injecting portion 660 and the ejecting portion 670 are not connected to the groove GV, but are connected to an additional groove AGV arranged radially inwardly from the groove GV. For example, the first mold 610 further includes the additional groove AGV that is extends from the groove GV toward the center of the first mold 610 in a plan view, that is, extends in an inwardly radial direction. The injecting portion 660 and the ejecting portion 670 are connected to the additional groove AGV. According to an embodiment, the additional groove AGV includes a first additional groove AGV1 connected to the injecting portion 660 and a second additional groove AGV2 connected to the ejecting portion 670. The first additional groove AGV1 is filled with the resins, and thus, the first circumferential protrusion portion 421 (see FIG. 5) described above can be formed. The second additional groove AGV2 is filled with the resins, and thus, the second circumferential protrusion portion 422 (see FIG. 5) described above can be formed.

The injecting portion 660 and the ejecting portion 670 are spaced apart from each other along the circumference of the first mold 610 in a plan view. For example, an angle between the injecting portion 660 and the ejecting portion 670 is greater than 0 degrees and less than or equal to 180 degrees.

In an embodiment, the injecting portion 660 and the ejecting portion 670 are symmetrically arranged with respect to the center of the first mold 610 in the plan view. For example, the angle between the injecting portion 660 and the ejecting portion 670 is 180 degrees. Accordingly, the entire GV can be substantially completely filled with the resins. In addition, the first additional groove AGV1 and the second additional groove AGV2 connected to the injecting portion 660 and the ejecting portion 670, respectively, are symmetrically arranged with respect to the center of the first mold 610 in the plan view. For example, an angle between the first additional groove AGV1 and the second additional groove AGV2 is 180 degrees.

According to an embodiment, the additional groove AGV has less depth than the groove GV. That is, a distance d2 from a surface of the display module 500 to a lower surface of the additional groove AGV is less than a distance d1 from a surface of the display module 500 to a lower surface of the groove GV. Therefore, a resin dispenser inserted into the injecting portion 660 can inject the resins while being adjacent to the display module 500. In addition, a thickness of the circumferential protrusion portion 420 (see FIG. 5) formed to correspond to the additional groove AGV is less than a thickness of the circumferential member 410. This allows a manufacturing process of a display apparatus in which the circumferential protrusion portion 420 does not interfere when the resin structure 400 is connected to an electronic device.

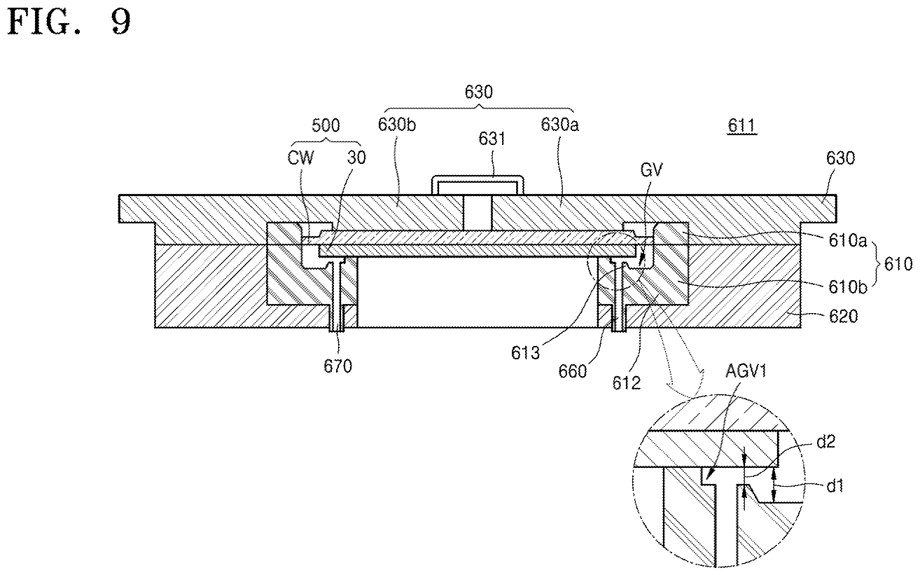

FIG. 9 is a cross-sectional view of an apparatus for manufacturing a display apparatus, according to another embodiment. Components that are the same as described above are denoted with the same members, and thus, repeated descriptions are omitted, and hereinafter, only aspects that are different from the apparatus 2 for manufacturing a display apparatus described above will be mainly described.

Referring to FIG. 9, according to an embodiment, the first mold 610 includes a 1-1^{st} mold 610a and a 1-2^{nd} mold 610b. The 1-1^{st} mold 610a is accommodated in the third mold 630, and, the 1-2^{nd} mold 610b is accommodated in the second mold 620.

The display module 500 is accommodated in the third mold 630. For example, the third mold 630 accommodates the display module 500 while facing the cover window CW of the display module 500. The 1-1^{st} mold 610a is disposed at an inner portion of the third mold 630 and has a ring shape that surrounds the display module 500, such as, an outer circumference of the cover window CW.

The second mold 620 is coupled to the third mold 630 to cover the display module 500. For example, the second mold 620 is coupled to the third mold 630 while facing the panel 30 of the display module 500. Similar to the description above, the 1-2^{nd} mold 610b includes the vertical portion 611, the horizontal portion 612, and the protrusion bump portion 613, and the vertical portion 611 of the 1-2^{nd} mold 610b contacts the 1-1^{st} mold 610a. In addition, the protrusion bump portion 613 contacts the display module 500, such as the panel 30. Accordingly, an encapsulated space can be formed between the 1-1^{st} mold 610a, the 1-2^{nd} mold 610b, and the display module 500. Resins are injected into the encapsulated space and cured to form the resin structure 400 (see FIG. 1) described above.

In addition, according to an embodiment, the third mold 630 is split into a plurality of members. For example, as illustrated in FIG. 9, the third mold 630 includes a 3-1^{st} mold 630a and a 3-2^{nd} mold 630b. Each of the 3-1^{st} mold 630a and the 3-2^{nd} mold 630b accommodates a portion of the display module 500, and the 3-1^{st} mold 630a and the 3-2^{nd} mold 630b are spaced apart from each other by a predetermined distance.

A distance adjusting portion 631 is disposed between the 3-1^{st} mold 630a and the 3-2^{nd} mold 630b. The distance adjusting portion 631 can adjust the distance between the 3-1^{st} mold 630a and the 3-2^{nd} mold 630b. Thus, after the display module 500 is accommodated in a state in which the distance between the 3-1^{st} mold 630a and the 3-2^{nd} mold 630b is increased, the distance between the 3-1^{st} mold 630a and the 3-2^{nd} mold 630b can be reduced by using the distance adjusting portion 631. Thus, the display module 500 can be pressed more tightly toward the 1-1^{st} mold 610a and provides a relatively tighter encapsulation.

According to an embodiment, the distance adjusting portion 631 includes a clamp. For example, by tightening the clamp, the distance between the 3-1^{st} mold 630a and the 3-2^{nd} mold 630b can be reduced, and by loosening the clamp, the distance between the 3-1^{st} mold 630a and the 3-2^{nd} mold 630b can be increased. However, the distance adjusting portion 631 is not necessarily limited to the above example, and may be realized as various types.

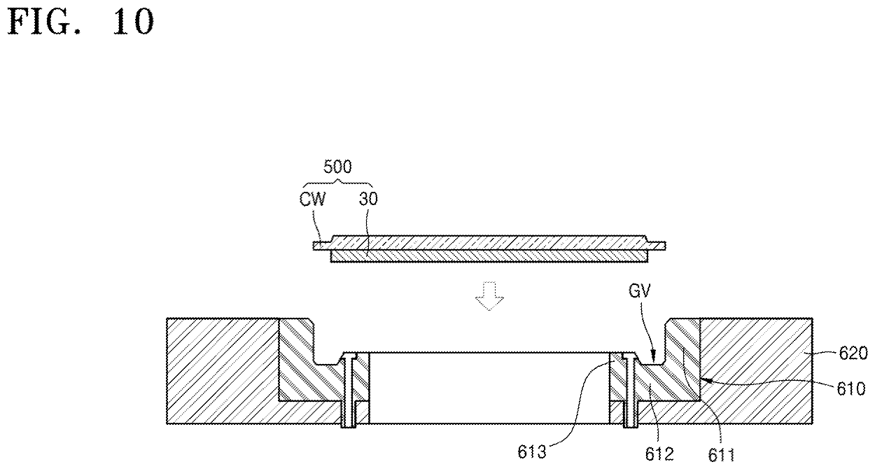

FIGS. 10 to 14 illustrate a method of manufacturing a display apparatus, according to an embodiment. Hereinafter, for convenience of description, a method of manufacturing a display apparatus is described by using an apparatus for manufacturing a display apparatus illustrated in FIGS. 6A, 6B, 7 and 8. However, a method of manufacturing a display apparatus is not necessarily limited thereto.

Referring to FIG. 10, in an embodiment, the first mold 610 is accommodated in the second mold 620. The display module 500 is accommodated in the second mold 620, such as in the first mold 610 at an inner portion of the second mold 620. The display module 500 is accommodated such that a surface of the panel 30, such as an opposite surface of a display surface, faces the first mold 610 and the second mold 620. The vertical portion 611 of the first mold 610 surrounds an outer circumference of the cover window CW of the display module 500. The horizontal portion 612 extends from the vertical portion 611 in an inwardly radial direction, and the protrusion bump portion 613 protrudes from the horizontal portion 612 toward the panel 30. Thus, the first mold 610 includes the groove GV formed along a circumference of the display module 500.

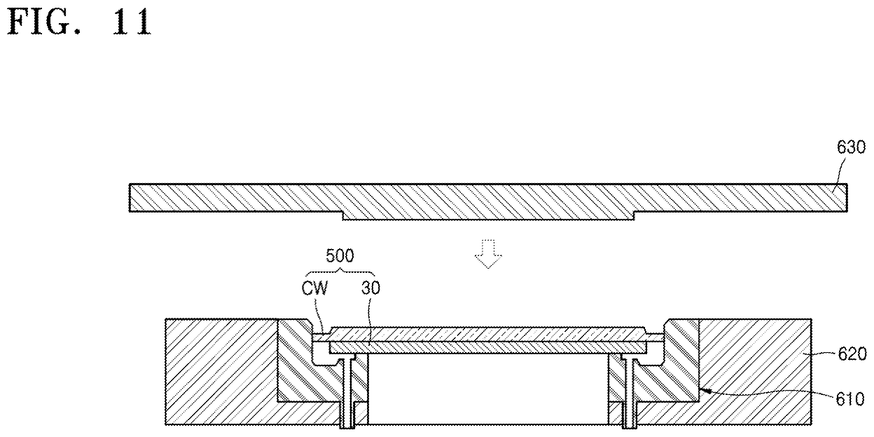

Referring to FIG. 11, in an embodiment, the third mold 630 is coupled to the second mold 620 and covers the display module 500. As described above, according to an embodiment, the second mold 620 and the third mold 630 are coupled to each other through a coupling hole and a fixing member that includes a thread.

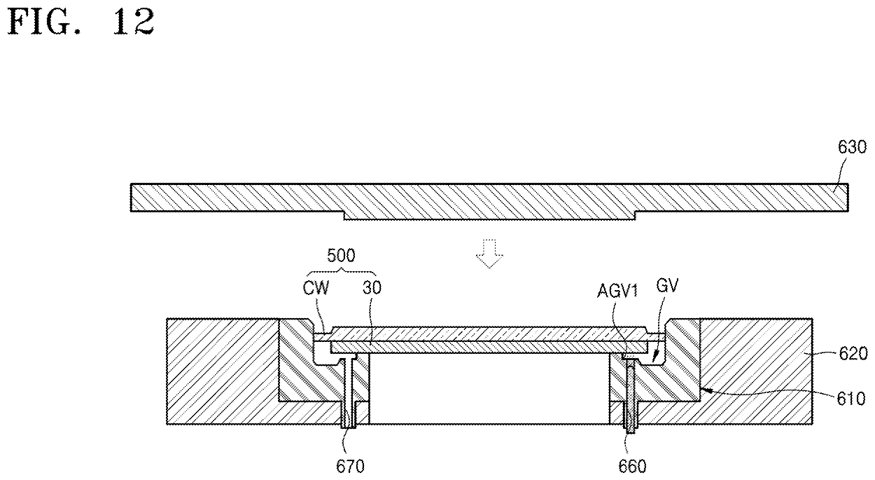

Referring to FIG. 12, in an embodiment, a resin dispenser is inserted through the injecting portion 660, and injects resins into the first additional groove AGV1. Through the first additional groove AGV1, the injected resins completely fill the encapsulated space between the groove GV and the display module 500, and the overflowing resins are ejected through the ejecting portion 670.

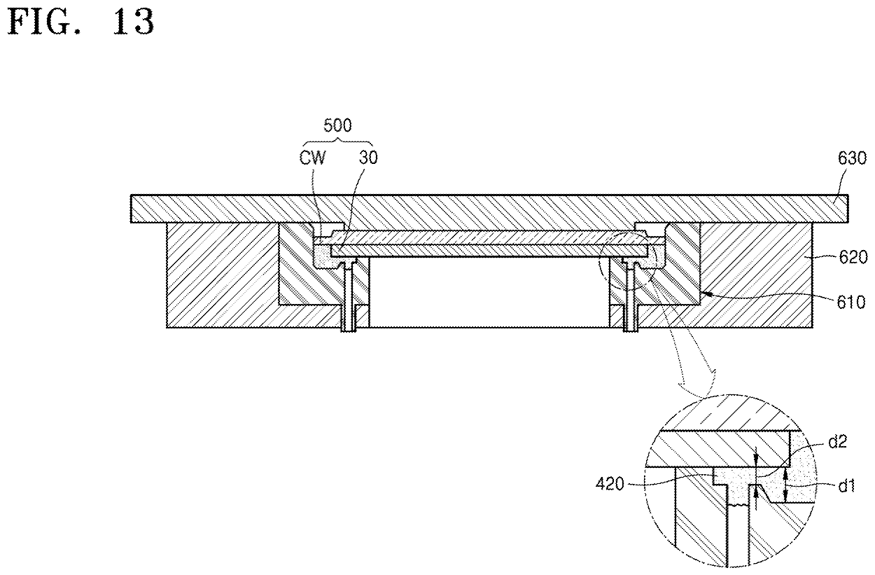

Referring to FIG. 13, in an embodiment, a thermosetting process is performed that cures the resins that fill the groove GV and the additional groove AGV. Thus, the resin structure 400 is formed along a circumference of the display module 500. In addition, the circumferential protrusion portion 420 is formed at a position that corresponds to the injecting portion 660 and the ejecting portion 670.

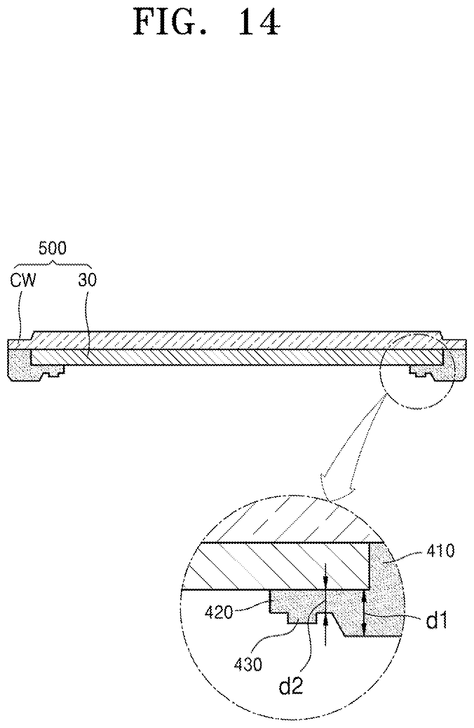

Referring to FIG. 14, in an embodiment, the apparatus 2 for manufacturing a display apparatus is removed. For example, the first, second and third molds 610, 620 and 630 are removed from the display module 500. In addition, residues of the resins injected and ejected through the injecting portion 660 and the ejecting portion 670, respectively, are cut. Accordingly, the cutting column 430 that protrudes from the circumferential protrusion portion 420 is formed. Even when the residues of the resins are cut, the cutting column 430 is closer to the panel 30 in a thickness direction than the second surface 412 of the circumferential member 410. Thus, after the residues of the resins are cut, the cutting column 430 protrudes from the second surface 412 of the circumferential member 410, and thus, interference which can occur when the display apparatus 1 is connected to an electronic device can be prevented.

As described above, according to one or more embodiments of the disclosure, the quality of a resin structure of the display apparatus is increased.

In addition, the resin structure of the display apparatus is easily formed.

Effects of the one or more embodiments described above are not limited to those described above, and other effects that not are described can be clearly understood by one of ordinary skill in the art from the disclosure or the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details can be made therein without departing from the spirit and scope as defined by the following claims.

What is claimed is:

1. An apparatus for manufacturing a display apparatus, comprising:
a first mold that includes an open surface that accommodates a display module;
a second mold that surrounds the first mold and accommodates the first mold; and
a third mold coupled to the second mold so that the third mold covers the accommodated display module,
wherein a modulus of the first mold is lower than a modulus of the second mold.

2. The apparatus for manufacturing a display apparatus of claim 1, wherein the first mold includes silicon, and the second mold includes a metal.

3. The apparatus for manufacturing a display apparatus of claim 1, wherein the first mold includes a groove formed along a circumference of the accommodated display module, wherein the groove is concave in a thickness direction of the first mold.

4. The apparatus for manufacturing a display apparatus of claim 3, wherein the groove is defined by a vertical portion of the first mold that contacts the circumference of the display module and extends in a direction perpendicular to a display surface of the display module, a horizontal portion of the first mold that extends from the vertical portion toward a center of the first mold in a plan view, and a protrusion bump portion of the first mold that protrudes from the horizontal portion toward the display module.

5. The apparatus for manufacturing a display apparatus of claim 4, wherein, in a plan view, a radius of an outer circumference of the groove is less than a radius of an outer circumference of the display module.

6. The apparatus for manufacturing a display apparatus of claim 4, wherein the vertical portion is chamfered at an entrance of the groove.

7. The apparatus for manufacturing a display apparatus of claim 4, wherein a portion at which the vertical portion and the horizontal portion are connected to each other is chamfered.

8. The apparatus for manufacturing a display apparatus of claim 3, further comprising:
an injecting portion through which resins are injected into an encapsulated space formed by the groove and the display module accommodated in the first mold; and
an ejecting portion through which the resins are ejected after the encapsulated space is completely filled with the resins,
wherein, in a plan view, each of the injecting portion and the ejecting portion is located inward from the groove in a radial direction.

9. The apparatus for manufacturing a display apparatus of claim 8, wherein the injecting portion and the ejecting portion are symmetrically arranged with respect to a center of the first mold, in a plan view.

10. The apparatus for manufacturing a display apparatus of claim 8, wherein each of the injecting portion and the ejecting portion is a through-hole that extends in a direction perpendicular to a display surface of the display module.

11. The apparatus for manufacturing a display apparatus of claim 10, wherein inner surfaces of the injecting portion and the ejecting portion include a same material as the first mold.

12. The apparatus for manufacturing a display apparatus of claim 9, wherein the first mold further includes an additional groove that extends from the groove toward the center of the first mold in the plan view, and
each of the injecting portion and the ejecting portion is connected to the additional groove.

13. The apparatus for manufacturing a display apparatus of claim 12, wherein the additional groove includes a first additional groove connected to the injecting portion and a second additional groove connected to the ejecting portion, and
the first additional groove and the second additional groove are symmetrically arranged with respect to the center of the first mold in the plan view.

14. The apparatus for manufacturing a display apparatus of claim 13, wherein a depth of the additional groove is less than a depth of the groove.

15. The apparatus for manufacturing a display apparatus of claim 1, further comprising a coupling portion that couples the second mold with the third mold,
wherein the coupling portion includes a coupling hole that penetrates the second mold and the third mold and a fixing member inserted into the coupling hole.

16. A display apparatus, comprising:
a panel that includes a display panel and a support panel that supports the display panel;
a cover window that covers the display panel at a side opposite to the support panel, and is larger than the display panel in a plan view; and
a resin structure disposed along a circumference of the panel at a side opposite to the cover window with the panel between the resin structure and cover window,
wherein an outer circumferential surface of the resin structure includes a concave surface that is curved toward a center of the panel in the plan view.

17. The display apparatus of claim 16, wherein the resin structure includes:
a circumferential member that forms a closed loop along the circumference of the panel; and
a circumferential protrusion portion that protrudes from the circumferential member toward the center of the panel in the plan view.

18. The display apparatus of claim 17, wherein a thickness of the circumferential protrusion portion is less than a thickness of the circumferential member.

19. The display apparatus of claim 17, wherein the circumferential protrusion portion includes a first circumferential protrusion portion and a second circumferential protrusion portion, and
the first circumferential protrusion portion and the second circumferential protrusion portion are symmetrically arranged with respect to the center of the panel in the plan view.

20. The display apparatus of claim 17, wherein the resin structure further includes a cutting column that protrudes in a direction away from a surface of the panel, wherein the cutting column is closer to the panel in a thickness direction than the circumferential member.

21. A method of manufacturing a display apparatus, comprising:
accommodating a first mold in a second mold, and accommodating a display module in the second mold, wherein the first mold includes a groove formed along a circumference of the display module;
coupling a third mold to the second mold so that the third mold covers the display module;
injecting resins through an injecting portion and into the groove, wherein the injecting portion penetrates the first and second molds;
curing the resins by performing a thermosetting process so that a resin structure is formed along a circumference of the display module, wherein a circumferential protrusion portion of the resin structure is formed at a position that corresponds to the injecting portion and the ejecting portion; and
removing the first, second and third molds from the display module, and cutting residues of the resins so that a cutting column that protrudes from the circumferential protrusion portion of the resin structure is formed.

22. The method of claim 21, wherein the display module includes a cover window, a vertical portion of the first mold surrounds an outer circumference of the cover window of the display module, a horizontal portion extends from the vertical portion in an inwardly radial direction, and a protrusion bump portion protrudes from the horizontal portion toward the panel.

23. The method of claim 21, wherein the second mold and the third mold are coupled to each other through a coupling hole and a fixing member that includes a thread.

24. The method of claim 21, wherein the resins are injected into a first additional groove connected to the groove, the injected resins completely fill an encapsulated space between the groove and the display module, and overflowing resins are ejected through an ejecting portion that penetrates the first and second molds.
